(19) United States
(12) Patent Application Publication
(10) Pub. No.: US 2025/0069851 A1
(43) Pub. Date: Feb. 27, 2025

(54) PLASMA PROCESSING APPARATUS AND PLASMA PROCESSING METHOD

(71) Applicant: Tokyo Electron Limited, Tokyo (JP)

(72) Inventors: Chishio KOSHIMIZU, Miyagi (JP); Shinji HIMORI, Miyagi (JP)

(73) Assignee: Tokyo Electron Limited, Tokyo (JP)

(21) Appl. No.: 18/944,017

(22) Filed: Nov. 12, 2024

(30) Foreign Application Priority Data
May 19, 2022 (JP) 2022-082271

(51) Int. Cl. H01J 37/32

(52) U.S. Cl. CPC H01J 37/32146; H01J 37/32642; H01J 37/32715; H01J 2237/2007

(57) ABSTRACT

A plasma processing apparatus includes a chamber, a substrate support, a radio-frequency power supply, and a bias power supply system. The substrate support is in the chamber and includes a central portion on which a substrate is placeable. The radio-frequency power supply generates source radio-frequency power. The bias power supply system respectively provides first electrical bias energy and second electrical bias energy to a first electrode and a second electrode. The first electrode is at least in the central portion of the substrate support. The second electrode is in an outer portion located outward from the central portion in a radial direction that is radial from a center of the central portion. The bias power supply system adjusts the first and second electrical bias energy to increase electric field strength above one of the central portion or the outer portion earlier than electric field strength above the other portion.

### CROSS-REFERENCE TO RELATED APPLICATIONS

The present application is a continuation of PCT International Application No. PCT/JP2023/017307 filed on May 8, 2023, which claims priority under 35 U.S.C. § 119 (a) to Application No. JP 2022-082271 filed on May 19, 2022 in Japan, all of which are hereby expressly incorporated by reference into the present application.

### FIELD

Exemplary embodiments of the disclosure relate to a plasma processing apparatus and a plasma processing method.

### BACKGROUND

A plasma processing apparatus is used to perform plasma processing on substrates. The plasma processing apparatus includes a chamber, an electrostatic chuck (ESC), and a lower electrode. The ESC and the lower electrode are in the chamber. The ESC is on the lower electrode. The ESC supports an edge ring placed on the ESC. The edge ring may be referred to as a focus ring. The ESC supports a substrate placed in an area surrounded by the edge ring. A gas is supplied into the chamber for plasma processing in the plasma processing apparatus. Radio-frequency (RF) power is provided to the lower electrode. This causes the gas in the chamber to generate plasma. The substrate is processed with a chemical species such as ions or radicals in the plasma.

Through plasma processing, the edge ring wears and has a smaller thickness. The edge ring having a smaller thickness causes a plasma sheath (hereafter, a sheath) above the edge ring to have its upper end at a lower position. The sheath above the edge ring is to have, in the vertical direction, its upper end at a position aligned with the position of the upper end of the sheath above the substrate. Patent Literature 1 below describes a technique for applying a direct current (DC) voltage to an edge ring to adjust the position of the upper end of the sheath above the edge ring in the vertical direction.

### CITATION LIST

### Patent Literature

Patent Literature 1: Japanese Unexamined Patent Application Publication No. 2008-227063

### BRIEF SUMMARY

### Technical Problem

One or more aspects of the disclosure are directed to a technique for adjusting the distribution of the plasma density in a chamber.

### Solution to Problem

A plasma processing apparatus according to an exemplary embodiment includes a chamber, a substrate support, a radio-frequency power supply, and a bias power supply system. The substrate support is in the chamber and includes a central portion on which a substrate is placeable. The radio-frequency power supply generates source radio-frequency power to generate plasma from a gas in the chamber. The bias power supply system provides first electrical bias energy to a first electrode and second electrical bias energy to a second electrode. The first electrode is at least in the central portion. The second electrode is in an outer portion located outward from the central portion in a radial direction. The radial direction is radial from a center of the central portion. The bias power supply system adjusts the first electrical bias energy and the second electrical bias energy to increase electric field strength above one of the central portion or the outer portion earlier than electric field strength above the other of the central portion or the outer portion.

### Advantageous Effects

The technique according to one exemplary embodiment adjusts the distribution of the plasma density in the chamber.

### BRIEF DESCRIPTION OF DRAWINGS

FIG. 1 is a diagram of a plasma processing system with an example structure.

FIG. 2 is a diagram of a capacitively coupled plasma processing apparatus with an example structure.

FIG. 3 is a timing chart for a plasma processing apparatus according to one exemplary embodiment.

FIG. 4 is a timing chart for a plasma processing apparatus according to one exemplary embodiment.

FIG. 5 is a timing chart for a plasma processing apparatus according to one exemplary embodiment.

FIG. 6 is a timing chart for a plasma processing apparatus according to one exemplary embodiment.

FIG. 7 is a diagram of a plasma processing apparatus according to another exemplary embodiment.

FIG. 8 is a diagram of a plasma processing apparatus according to still another exemplary embodiment.

FIG. 9 is a diagram of a plasma processing apparatus according to still another exemplary embodiment.

FIG. 10 is a timing chart for a plasma processing apparatus according to still another exemplary embodiment.

FIG. 11 is a flowchart of a plasma processing method according to one exemplary embodiment.

### DETAILED DESCRIPTION

Exemplary embodiments will now be described in detail with reference to the drawings. In the figures, like reference numerals denote like or corresponding components.

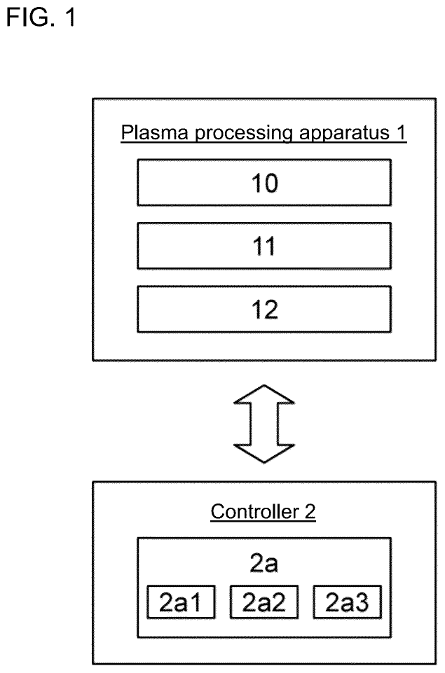

FIG. 1 is a diagram of a plasma processing system with an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet port is connected to a gas supply 20 (described later). The gas outlet is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be, for example, capacitively coupled plasma (CCP), inductively coupled plasma (ICP), electron cyclotron resonance (ECR) plasma, helicon wave excitation plasma (HWP), or surface wave plasma (SWP).

The controller 2 processes computer-executable instructions that cause the plasma processing apparatus 1 to perform various steps described in one or more embodiments of the disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2al may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2al. The medium may be one of various storage media readable by the computer 2a, or a communication line connected to the communication interface 2a3. The processor 2al may be a central processing unit (CPU). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. The storage 2a2 may include a random-access memory (RAM), a read-only memory (ROM), a hard disk drive (HDD), a solid-state drive (SSD), or a combination of these. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC. The communication interface 2a3 may communicate with the plasma processing apparatus 1 through a communication line such as a local area network (LAN).

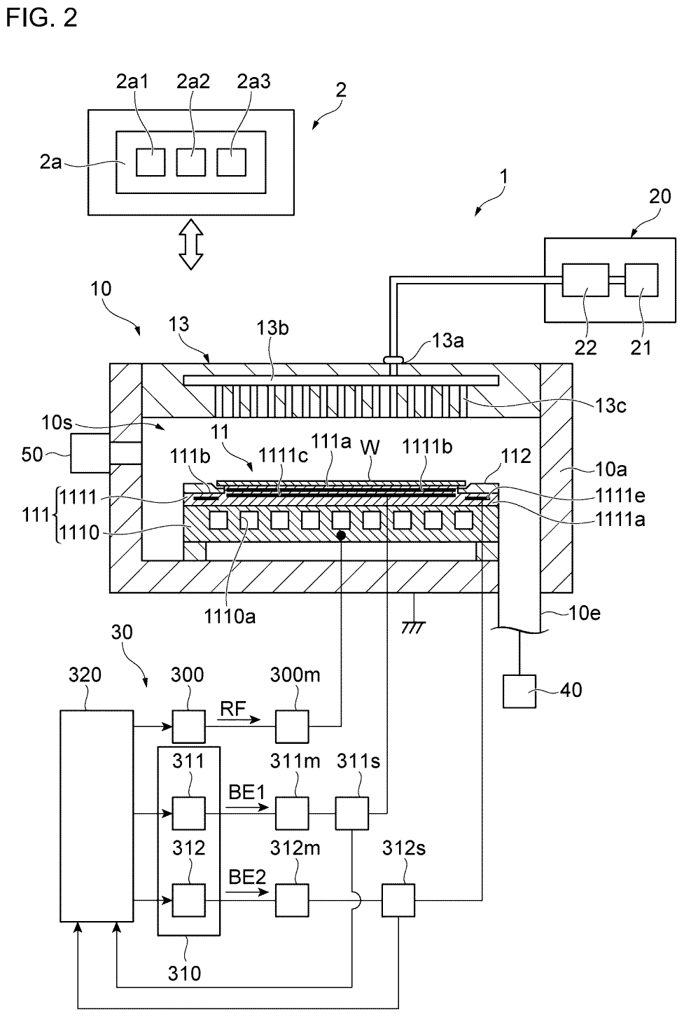

An example structure of a capacitively coupled plasma processing apparatus as an example of the plasma processing apparatus 1 will now be described. FIG. 2 is a diagram of the capacitively coupled plasma processing apparatus with the example structure.

The capacitively coupled plasma processing apparatus 1 includes the plasma processing chamber 10, the gas supply 20, a power supply system 30, and the exhaust system 40. The plasma processing apparatus 1 also includes the substrate support 11 and a gas inlet unit. The gas inlet unit allows at least one process gas to be introduced into the plasma processing chamber 10. The gas inlet unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The substrate support 11 is electrically insulated from the housing of the plasma processing chamber 10.

The substrate support 11 includes a body 111 and an edge ring 112. The body 111 includes a central portion 111a for supporting a substrate W and an annular portion 111b for supporting the edge ring 112. The substrate W is, for example, a wafer. The edge ring 112 is formed from a conductive material or an insulating material. The annular portion 111b of the body 111 surrounds the central portion 111a of the body 111 as viewed in plan. The substrate W is placed on the central portion 111a of the body 111. The edge ring 112 is placed on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the edge ring 112.

In one embodiment, the body 111 includes a base 1110 and an electrostatic chuck (ESC) 1111. The base 1110 includes a conductive member. The ESC 1111 is located on the base 1110. The ESC 1111 includes a ceramic member 1111a and an electrostatic electrode 1111b inside the ceramic member 1111a. The ceramic member 1111a serves as the central portion 111a. In one embodiment, the ceramic member 1111a also serves as the annular portion 111b. Another member surrounding the ESC 1111, such as an annular ESC or an annular insulating member, may serve as the annular portion 111b. In this case, the edge ring 112 may be placed on the annular ESC or the annular insulating member, or may be placed on both the ESC 1111 and the annular insulating member.

The substrate support 11 may also include a temperature control module that adjusts the temperature of at least one of the ESC 1111, the edge ring 112, or the substrate to a target temperature. The temperature control module may include at least one heater, a heat transfer medium, at least one channel 1110a, or a combination of these. The channel 1110a allows a heat transfer fluid such as brine or gas to flow. In one embodiment, the channel 1110a is defined in the base 1110, and one or more heaters are located in the ceramic member 1111a in the ESC 1111. The substrate support 11 may include a heat transfer gas supply to supply a heat transfer gas into a space between the back surface of the substrate W and the central portion 111a.

The shower head 13 introduces at least one process gas from the gas supply 20 into the plasma processing space 10s. The shower head 13 has at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas inlet unit may include one or more side gas injectors (SGIs) installed in one or more openings in the side wall 10a.

The gas supply 20 may include at least one gas source 21 and at least one flow controller 22. In one embodiment, the gas supply 20 allows supply of at least one process gas from the corresponding gas source 21 to the shower head 13 through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

The power supply system 30 includes a radio-frequency (RF) power supply 300 and a bias power supply system 310. The RF power supply 300 serves as the plasma generator 12 in one embodiment. The RF power supply 300 generates source radio-frequency power RF. The source radio-frequency power RF has a source frequency fRF. More specifically, the source radio-frequency power RF has a sinusoidal waveform with its frequency being the source frequency fRF. The source frequency fRF may be within a range of 10 to 150 MHz. The RF power supply 300 is electrically coupled to an RF electrode through a matcher 300m to provide the source radio-frequency power RF to the RF electrode. The RF electrode may be located in the substrate support 11. The RF electrode may be the conductive member in the base 1110 or may be at least one electrode in the ceramic member 1111a. In some embodiments, the RF electrode may be the upper electrode. In response to the source radio-frequency power RF provided to the RF electrode, plasma is generated from the gas in the chamber 10.

The matcher 300m has a variable impedance. The variable impedance of the matcher 300m is set to reduce reflection of the source radio-frequency power RF from a load. The matcher 300m may be controlled by, for example, the controller 2.

The bias power supply system 310 provides first electrical bias energy BE1 to a first electrode and second electrical bias energy BE2 to a second electrode. The bias power supply system 310 includes an output of the first electrical bias energy BE1 and an output of the second electrical bias energy BE2. The output of the first electrical bias energy BE1 is electrically coupled to the first electrode. The output of the second electrical bias energy BE2 is electrically coupled to the second electrode. In one embodiment, the bias power supply system 310 may include a first power supply 311 that generates the first electrical bias energy BE1 and a second power supply 312 that generates the second electrical bias energy BE2.

The first electrode is located at least in the central portion 111a. In one embodiment, the first electrode is an electrode 1111c. The electrode 1111c is located in the ESC 1111 in the central portion 111a. The electrode 1111c may be a film of a conductive material.

The second electrode is located in an outer portion. The outer portion is located outward from the central portion 111a in a radial direction. The radial direction herein is a direction radial from the center (e.g., central axis) of the central portion 111a. In one embodiment, the second electrode is an electrode 1111e. The electrode 1111e is located in the ESC 1111 in the annular portion 111b. In one embodiment, the outer portion is thus the annular portion 111b on which the edge ring 112 is placeable. The electrode 1111e may be a film of a conductive material. The electrode 1111e extends in a circumferential direction. The circumferential direction herein is a rotation direction with respect to the central axis of the central portion 111a. The electrode 1111e may be, for example, annular.

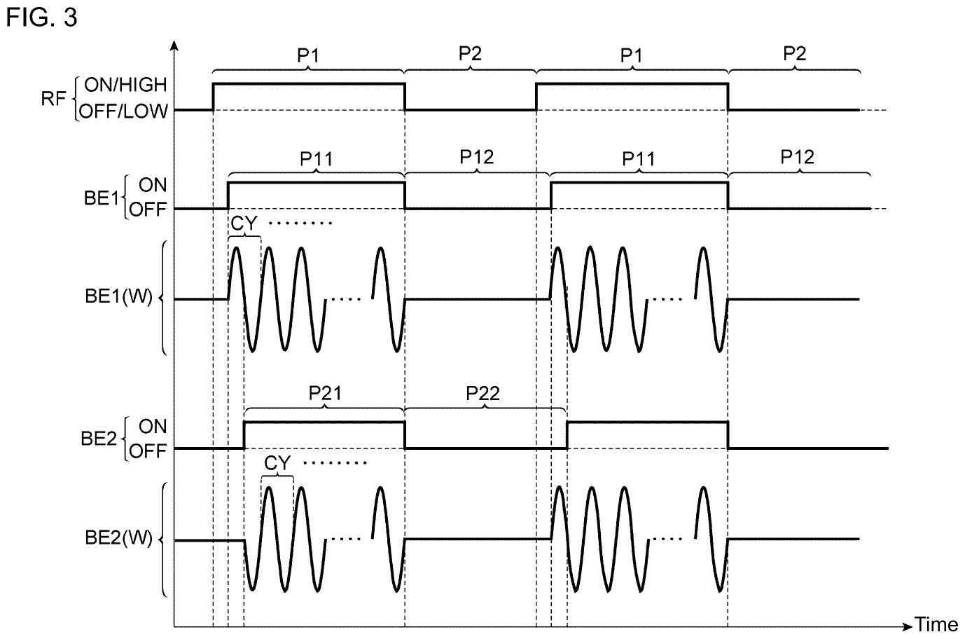

FIGS. 3 to 6 will now be referred to in addition to FIG. 2. FIGS. 3 to 6 are timing charts each for a plasma processing apparatus according to one exemplary embodiment. As shown in FIGS. 3 to 6, each of the first electrical bias energy BE1 and the second electrical bias energy BE2 has a waveform cycle CY and is provided cyclically. The waveform cycle CY is defined by a bias frequency. The bias frequency is lower than the source frequency, and is, for example, 50 kHz to 27 MHz inclusive. The waveform cycle CY has a time length that is the inverse of the bias frequency.

As shown in FIG. 3, each of the first electrical bias energy BE1 and the second electrical bias energy BE2 may be bias RF power having the bias frequency. In other words, each of the first electrical bias energy BE1 and the second electrical bias energy BE2 may have a sinusoidal waveform with its frequency being the bias frequency. In this case, the output of the first electrical bias energy BE1 in the bias power supply system 310 is electrically coupled to the first electrode through a matcher 311m. The matcher 311m has a variable impedance that is set to reduce reflection of the first electrical bias energy BE1 from the load. The output of the second electrical bias energy BE2 in the bias power supply system 310 is electrically coupled to the second electrode through a matcher 312m. The matcher 312m has a variable impedance that is set to reduce reflection of the second electrical bias energy BE2 from the load.

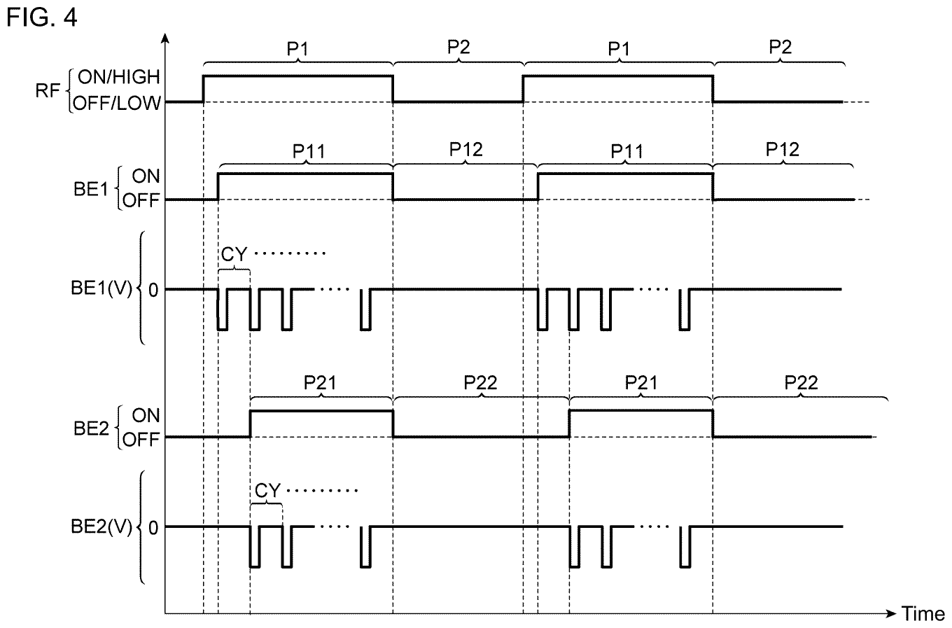

Each of the first electrical bias energy BE1 and the second electrical bias energy BE2 may include a voltage pulse as shown in FIGS. 4 to 6. The voltage pulse is generated in the waveform cycle CY. The waveform of the voltage pulse may be rectangular, triangular, or in any other shape. The voltage pulse may be a pulse of a negative voltage or a pulse of a negative direct current (DC) voltage. The voltage pulse of the first electrical bias energy BE1 is cyclically applied to the first electrode at a time interval equal to the time length of the waveform cycle CY. The voltage pulse of the second electrical bias energy BE2 is cyclically applied to the second electrode at the time interval equal to the time length of the waveform cycle CY. For the first electrical bias energy BE1 and the second electrical bias energy BE2 each including the voltage pulse, the plasma processing apparatus 1 may not include the matcher 311m and the matcher 312m.

As shown in FIGS. 3 to 6, the RF power supply 300 provides the source radio-frequency power RF to the RF electrode in a first period P1. In a second period P2, the RF power supply 300 stops providing the source radio-frequency power RF or provides, to the RF electrode, the source radio-frequency power RF having a different power level from the source radio-frequency power RF in the first period P1 (e.g., a power level lower than the power level of the source radio-frequency power RF in the first period P1). The first period P1 and the second period P2 alternate with each other. The RF power supply 300 identifies the first period P1 or the second period P2 based on a pulse control signal provided from a control circuit 320. The power level of the source radio-frequency power RF may be changed in each of the first period P1 and the second period P2.

The bias power supply system 310 cyclically provides the first electrical bias energy BE1 to the first electrode in an on-period P11. The bias power supply system 310 stops providing the first electrical bias energy BE1 in an off-period P12. The on-period P11 and the off-period P12 alternate with each other. A cycle including the on-period P11 and the off-period P12 has the same time length as a cycle including the first period P1 and the second period P2. The bias power supply system 310 identifies the on-period P11 or the off-period P12 based on a pulse control signal provided from the control circuit 320.

The bias power supply system 310 cyclically provides the second electrical bias energy BE2 to the second electrode in an on-period P21. The bias power supply system 310 stops providing the second electrical bias energy BE2 in an off-period P22. The on-period P21 and the off-period P22 alternate with each other. A cycle including the on-period P21 and the off-period P22 has the same time length as the cycle including the first period P1 and the second period P2. The bias power supply system 310 identifies the on-period P21 or the off-period P22 based on a pulse control signal provided from the control circuit 320.

The bias power supply system 310 matches the phase of the first electrical bias energy BE1 in the on-period P11 and the phase of the second electrical bias energy BE2 in the on-period P21 to each other. The bias power supply system 310 can match the phase of the first electrical bias energy BE1 and the phase of the second electrical bias energy BE2 to each other by identifying the on-period P11 and the on-period P21 based on the two pulse control signals described above.

When the first electrical bias energy BE1 is bias RF power, the control circuit 320 uses a voltage measurement value obtained by a sensor 311s to generate a pulse control signal. The sensor 311s measures the voltage on a feed line for the first electrical bias energy BE1. The feed line couples the matcher 311m and the first electrode. The first electrode has a potential that changes in the same cycle as the waveform cycle CY. Thus, the phase of the cycle in which the potential of the first electrode changes in response to the first electrical bias energy BE1 is determined based on the voltage measurement value obtained by the sensor 311s.

When the second electrical bias energy BE2 is bias RF power, the control circuit 320 uses a voltage measurement value obtained by a sensor 312s to generate a pulse control signal. The sensor 312s measures the voltage on a feed line for the second electrical bias energy BE2. The feed line couples the matcher 312m and the second electrode. The second electrode has a potential that changes in the same cycle as the waveform cycle CY. Thus, the phase of the cycle in which the potential of the second electrode changes in response to the second electrical bias energy BE2 is determined based on the voltage measurement value obtained by the sensor 312s.

The control circuit 320 generates the two pulse control signals described above based on the voltage measurement value obtained by the sensor 311s and the voltage measurement value obtained by the sensor 312s. This matches the phase of the first electrical bias energy BE1 in the on-period P11 and the phase of the second electrical bias energy BE2 in the on-period P21 to each other.

The bias power supply system 310 adjusts the first electrical bias energy BE1 and the second electrical bias energy BE2 to increase electric field strength above one of the central portion 111a or the outer portion described above earlier than electric field strength above the other of the central portion 111a or the outer portion. The plasma density tends to be higher above the portion above which the electric field strength increases first. Thus, in the plasma processing apparatus 1, the plasma density above one of the portions is relatively higher than the plasma density above the other portion. The plasma processing apparatus 1 can adjust the distribution of the plasma density in the radial direction in the chamber based on the principle described above. For example, the plasma processing apparatus 1 can adjust the distribution of the plasma density to be uniform in the radial direction in the chamber 10.

In one embodiment, as shown in FIGS. 3 and 4, the bias power supply system 310 may start providing the first electrical bias energy BE1 earlier than the second electrical bias energy BE2. The first electrical bias energy BE1 is started to be provided when the on-period P11 starts. The second electrical bias energy BE2 is started to be provided when the on-period P21 starts.

The bias power supply system 310 may start providing the second electrical bias energy BE2 earlier than the first electrical bias energy BE1.

More specifically, the bias power supply system 310 may start providing one of the first electrical bias energy BE1 or the second electrical bias energy BE2 earlier than the other of the first electrical bias energy BE1 or the second electrical bias energy BE2. This increases the electric field strength above one of the portions to which one of the first electrical bias energy BE1 or the second electrical bias energy BE2 is provided first earlier than the electric field strength above the other portion.

In another embodiment, each of the first electrical bias energy BE1 and the second electrical bias energy BE2 may include the voltage pulse described above. In this case, the bias power supply system 310 may adjust the voltage level of the voltage pulse of one of the first electrical bias energy BE1 or the second electrical bias energy BE2 at the start of electrical bias energy provision. The bias power supply system 310 may set the voltage level of the voltage pulse of the electrical bias energy at the start of electrical bias energy provision to a voltage level different from the voltage level of the voltage pulse of the electrical bias energy after the start of electrical bias energy provision.

The bias power supply system 310 may change the voltage level of the voltage pulse of the first electrical bias energy BE1 in the on-period P11. For example, the voltage level of the voltage pulse of the first electrical bias energy BE1 at the start of bias energy provision in the on-period P11 may be set to a voltage level different from the voltage level of the voltage pulse in a steady state after the start of bias energy provision in the on-period P11. The voltage pulse of the first electrical bias energy BE1 having a higher voltage level at the start of bias energy provision causes the plasma density above the central portion 111a to be relatively high. The voltage pulse of the first electrical bias energy BE1 having a lower voltage level at the start of bias energy provision causes the plasma density above the central portion 111a to be relatively low.

The bias power supply system 310 may change the voltage level of the voltage pulse of the second electrical bias energy BE2 in the on-period P21. For example, the voltage level of the voltage pulse of the second electrical bias energy BE2 at the start of bias energy provision in the on-period P21 may be set to a voltage level different from the voltage level of the voltage pulse in the steady state after the start of bias energy provision in the on-period P21. The voltage pulse of the second electrical bias energy BE2 having a higher voltage level at the start of bias energy provision causes the plasma density above the outer portion to be relatively high. The voltage pulse of the second electrical bias energy BE2 having a lower voltage level at the start of bias energy provision causes the plasma density above the outer portion to be relatively low.

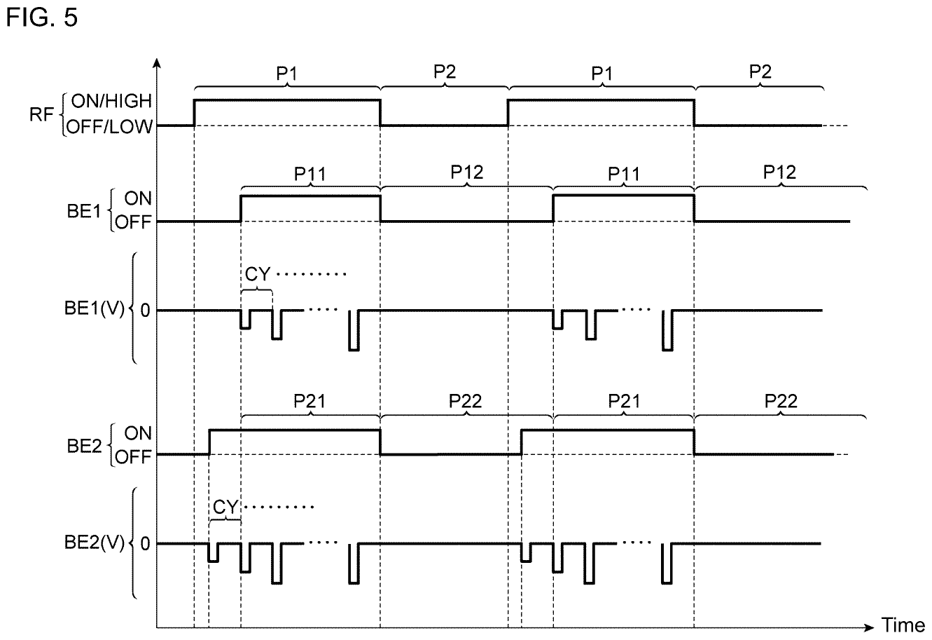

As shown in FIG. 5, the bias power supply system 310 may raise the voltage level (absolute value) of the voltage pulse of the first electrical bias energy BE1 to its voltage level in the steady state in a stepwise manner in the on-period P11. The bias power supply system 310 may raise the voltage level (absolute value) of the voltage pulse of the second electrical bias energy BE2 to its voltage level in the steady state in a stepwise manner in the on-period P21. The bias power supply system 310 may start the on-period P21 earlier than the on-period P11. The bias power supply system 310 may start the on-period P11 earlier than the on-period P21.

In still another embodiment, each of the first electrical bias energy BE1 and the second electrical bias energy BE2 may be bias RF power. In this case, the bias power supply system 310 may change the power level of one of the first electrical bias energy BE1 or the second electrical bias energy BE2. More specifically, the bias power supply system 310 may set the power level of the voltage pulse of the electrical bias energy at the start of bias energy provision to a power level different from the power level of the electrical bias energy after the start of bias energy provision.

The bias power supply system 310 may change the power level of the first electrical bias energy BE1 in the on-period P11. For example, the power level of the first electrical bias energy BE1 at the start of bias energy provision in the on-period P11 may be set to a power level different from the power level of the first electrical bias energy BE1 in the steady state after the start of bias energy provision in the on-period P11. The first electrical bias energy BE1 having a higher voltage level at the start of bias energy provision causes the plasma density above the central portion 111a to be relatively high. The first electrical bias energy BE1 having a lower voltage level at the start of bias energy provision causes the plasma density above the central portion 111a to be relatively low.

The bias power supply system 310 may change the power level of the second electrical bias energy BE2 in the on-period P21. For example, the power level of the second electrical bias energy BE2 at the start of bias energy provision in the on-period P21 may be set to a power level different from the power level of the second electrical bias energy BE2 in the steady state after the start of bias energy provision. The second electrical bias energy BE2 having a higher voltage level at the start of bias energy provision causes the plasma density above the outer portion to be relatively high. The second electrical bias energy BE2 having a lower voltage level at the start of bias energy provision causes the plasma density above the outer portion to be relatively low.

The bias power supply system 310 may raise the power level of the first electrical bias energy BE1 to its power level in the steady state in a stepwise manner in the on-period P11. The bias power supply system 310 may raise the power level of the second electrical bias energy BE2 to its power level in the steady state in a stepwise manner in the on-period P21. The bias power supply system 310 may start the on-period P21 earlier than the on-period P11. The bias power supply system 310 may start the on-period P11 earlier than the on-period P21.

In still another embodiment, each of the first electrical bias energy BE1 and the second electrical bias energy BE2 may include the voltage pulse described above. In this case, the bias power supply system 310 may change a duty cycle of the voltage of one of the first electrical bias energy BE1 or the second electrical bias energy BE2. The duty cycle is a percentage of the period in which the voltage pulse is provided in the waveform cycle CY. More specifically, the bias power supply system 310 may set the duty cycle of the electrical bias energy at the start of bias energy provision to a value different from the duty cycle of the electrical bias energy after the start of bias energy provision.

The bias power supply system 310 may change the duty cycle of the voltage pulse of the first electrical bias energy BE1 in the on-period P11. For example, the duty cycle of the voltage pulse of the first electrical bias energy BE1 at the start of bias energy provision in the on-period P11 may be set to a value different from the duty cycle of the voltage pulse in the steady state after the start of bias energy provision in the on-period P11. The voltage pulse of the first electrical bias energy BE1 with a higher duty cycle causes the plasma density above the central portion 111a to be relatively high. The voltage pulse of the first electrical bias energy BE1 with a lower duty cycle causes the plasma density above the central portion 111a to be relatively low.

The bias power supply system 310 may change the duty cycle of the voltage pulse of the second electrical bias energy BE2 in the on-period P21. For example, the duty cycle of the voltage pulse of the second electrical bias energy BE2 at the start of bias energy provision in the on-period P21 may be set to a value different from the duty cycle of the voltage pulse in the steady state after the start of bias energy provision in the on-period P21. The voltage pulse of the second electrical bias energy BE2 with a higher duty cycle causes the plasma density above the outer portion to be relatively high. The voltage pulse of the second electrical bias energy BE2 with a lower duty cycle causes the plasma density above the outer portion to be relatively low.

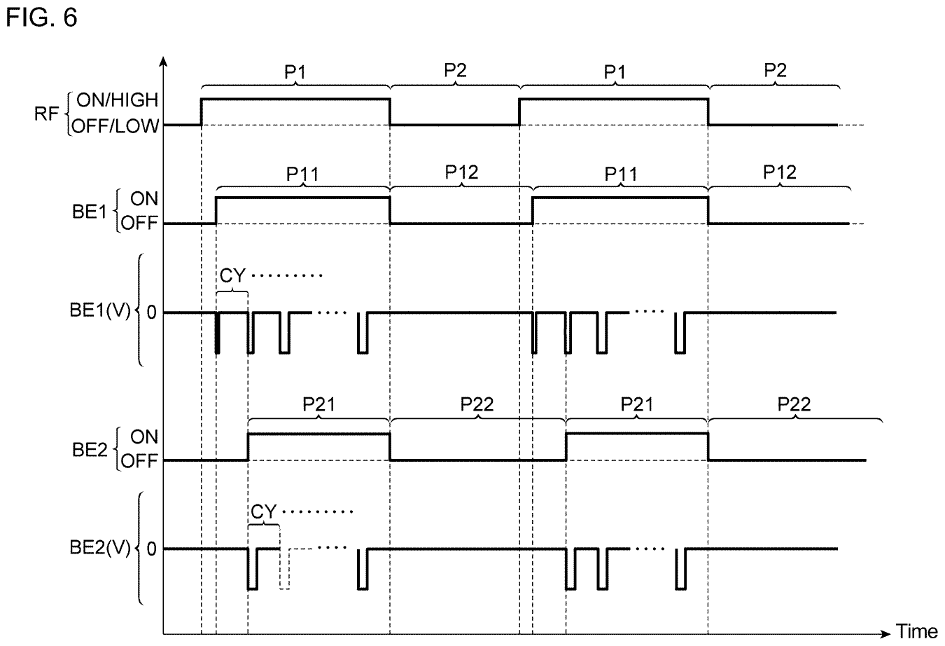

As shown in FIG. 6, the bias power supply system 310 may raise the duty cycle of the voltage pulse of the first electrical bias energy BE1 to its duty cycle in the steady state in a stepwise manner in the on-period P11. The bias power supply system 310 may instead or additionally raise the duty cycle of the voltage pulse of the second electrical bias energy BE2 to its duty cycle in the steady state in a stepwise manner in the on-period P21. The bias power supply system 310 may start the on-period P11 earlier than the on-period P21 as shown in FIG. 6. The bias power supply system 310 may start the on-period P21 earlier than the on-period P11.

In any of FIGS. 3 to 6, the source radio-frequency power RF is started to be provided earlier than the first electrical bias energy BE1 and the second electrical bias energy BE2. In other words, the first period P1 starts earlier than the on-period P11 and the on-period P21. However, the source radio-frequency power RF may be started to be provided earlier or later than at least one of the first electrical bias energy BE1 or the second electrical bias energy BE2. In other words, the first period P1 may start earlier or later than at least one of the on-period P11 or the on-period P21. The source radio-frequency power RF may be started to be provided earlier or later than at least one of the first electrical bias energy BE1 or the second electrical bias energy BE2 by a time length corresponding to five or fewer waveform cycles CY. In other words, the first period P1 may start earlier or later than at least one of the on-period P11 or the on-period P21 by the time length corresponding to five or fewer waveform cycles CY. The source radio-frequency power RF may be started to be provided earlier or later than at the time at least one of the first electrical bias energy BE1 or the second electrical bias energy BE2 is started to be provided by a time length greater than or equal to 1/100 or 1/50 of the waveform cycle CY.

The source radio-frequency power RF may be started to be provided at the same time as at least one of the first electrical bias energy BE1 or the second electrical bias energy BE2 is started to be provided. In other words, the first period P1 may start at the same time as at least one of the on-period P11 or the on-period P21 starts.

In one embodiment, the first electrical bias energy BE1 or the second electrical bias energy BE2 may be started to be provided earlier or later than the other of the first electrical bias energy BE1 or the second electrical bias energy BE2 by a time length. For example, one of the first electrical bias energy BE or the second electrical bias energy BE2 may be started to be provided earlier or later than the other of the first electrical bias energy BE1 or the second electrical bias energy BE2 by the time length corresponding to five or fewer waveform cycles CY. In other words, one of the on-period P11 or the on-period P21 may start earlier or later than the other of the on-period P11 or the on-period P21 by the time length corresponding to five or fewer waveform cycles CY.

In one embodiment, the control circuit 320 may generate the pulse control signals described above to cause each of the first electrical bias energy BE1, the second electrical bias energy BE2, and the source radio-frequency power RF to be started to be provided at the corresponding time designated by the controller 2. In this case, the controller 2 controls the control circuit 320 to cause each of the first electrical bias energy BE1, the second electrical bias energy BE2, and the source radio-frequency power RF to be started to be provided at a time determined based on a past process result or the light intensity in the chamber 10 or at a time stored in a database of the controller 2. The time at which each of the first electrical bias energy BE1, the second electrical bias energy BE2, and the source radio-frequency power RF is started to be provided is determined to, for example, cause the distribution of the plasma density in the chamber 10 to be uniform.

The light intensity in the chamber 10 is obtained by one or more optical emission spectrometers 50. The plasma processing apparatus 1 may include a single optical emission spectrometer 50 that measures the light intensity of plasma at multiple positions in the radial direction in the chamber 10 or two or more optical emission spectrometers. The controller 2 identifies a light intensity distribution of plasma in the chamber 10 based on the light intensity obtained by the one or more optical emission spectrometers 50. The controller 2 determines the time at which each of the first electrical bias energy BE1, the second electrical bias energy BE2, and the source radio-frequency power RF is started to be provided to cause the identified light intensity distribution to be uniform. The controller 2 may determine the time at which each of the first electrical bias energy BE1, the second electrical bias energy BE2, and the source radio-frequency power RF is started to be provided based on, for example, the bias current flowing through each of the first electrode and the second electrode or on changes in the potentials of some of the components in the chamber 10.

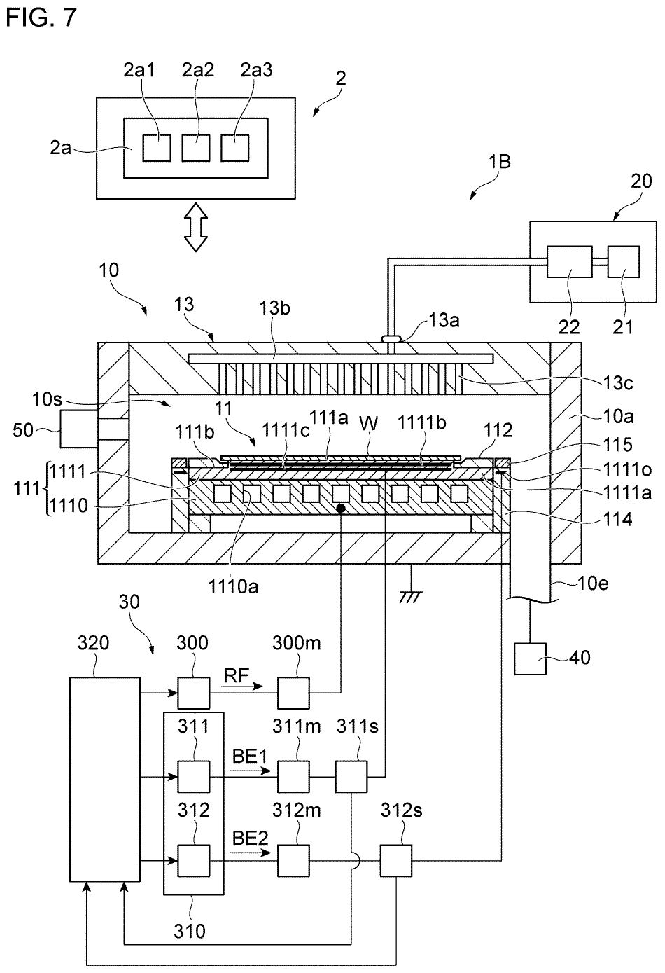

FIG. 7 will now be referred to. FIG. 7 is a diagram of a plasma processing apparatus according to another exemplary embodiment. A plasma processing apparatus 1B shown in FIG. 7 will now be described focusing on its differences from the plasma processing apparatus 1.

The plasma processing apparatus 1B further includes an outer peripheral portion 114 and an outer ring 115. The outer peripheral portion 114 is substantially cylindrical and extends along the outer periphery of the substrate support 11. The outer peripheral portion 114 is formed from an insulating material such as quartz. The outer ring 115 is on the outer peripheral portion 114. The outer ring 115 is substantially annular. The outer ring 115 is formed from the same material as the edge ring 112. The plasma processing apparatus 1B further includes an electrode 11110. The electrode 11110 is located below the outer ring 115 and in the outer peripheral portion 114. The plasma processing apparatus 1B does not include the electrode 1111e.

In the plasma processing apparatus 1B, the outer ring 115 serves as an outer peripheral area. In the plasma processing apparatus 1B, the outer peripheral area is thus located outward from the annular portion 111b in the radial direction. In the plasma processing apparatus 1B, the electrode 11110 serves as a second electrode. In the plasma processing apparatus 1B, the output of the second electrical bias energy BE2 in the bias power supply system 310 is electrically coupled to the electrode 11110. The other components of the plasma processing apparatus 1B are the same as the corresponding components of the plasma processing apparatus 1.

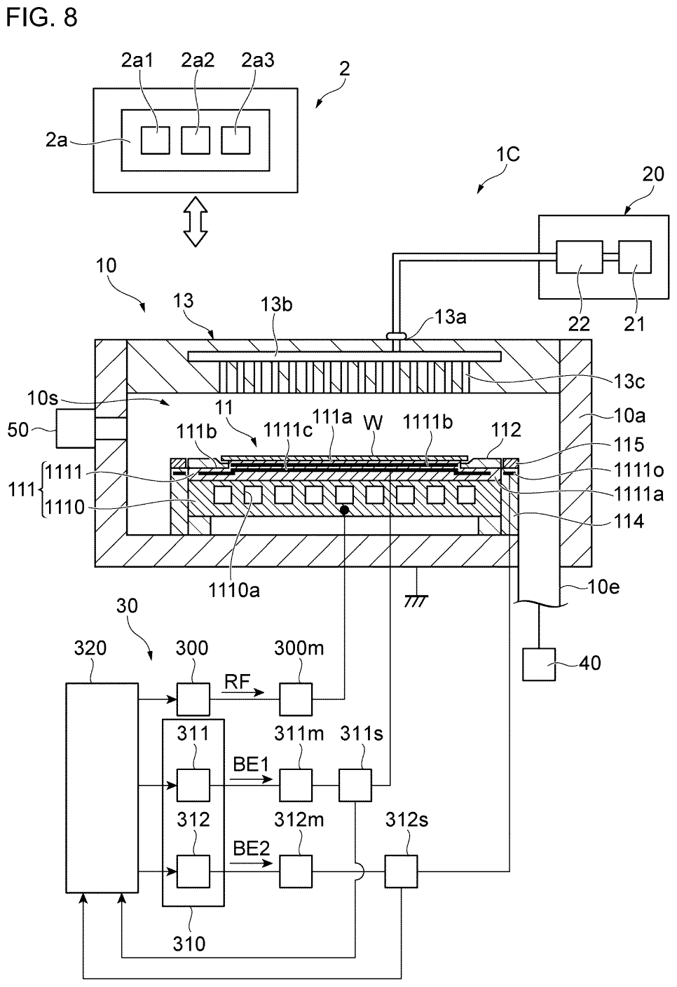

FIG. 8 will now be referred to. FIG. 8 is a diagram of a plasma processing apparatus according to still another exemplary embodiment. A plasma processing apparatus 1C shown in FIG. 8 will now be described focusing on its differences from the plasma processing apparatus 1B. The plasma processing apparatus 1C includes the electrode 1111c in the central portion 111a and the annular portion 111b in the ESC 1111. The other components of the plasma processing apparatus 1C are the same as the corresponding components of the plasma processing apparatus 1B.

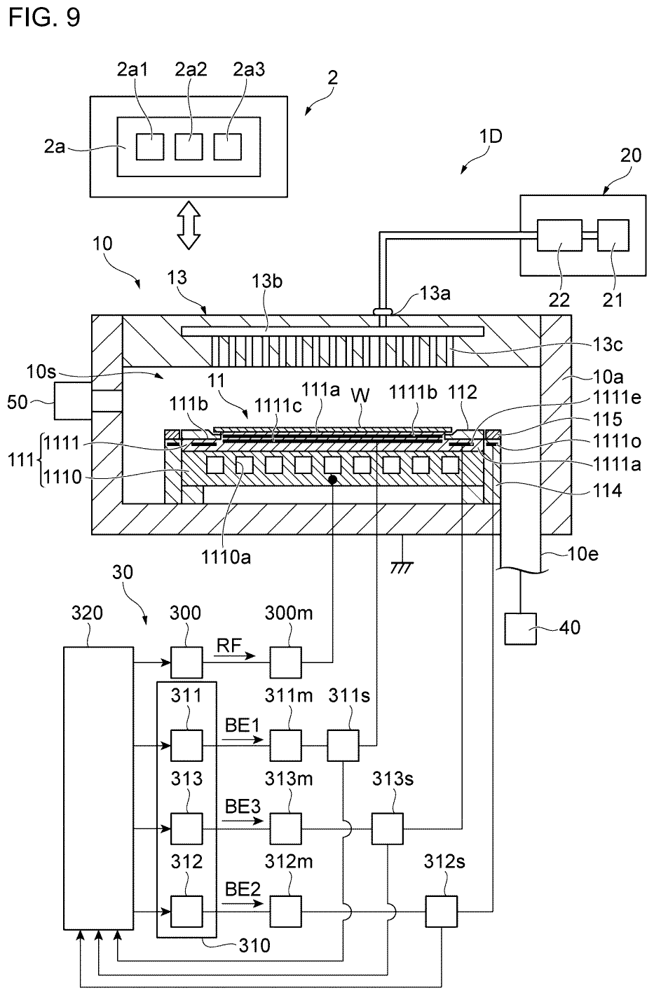

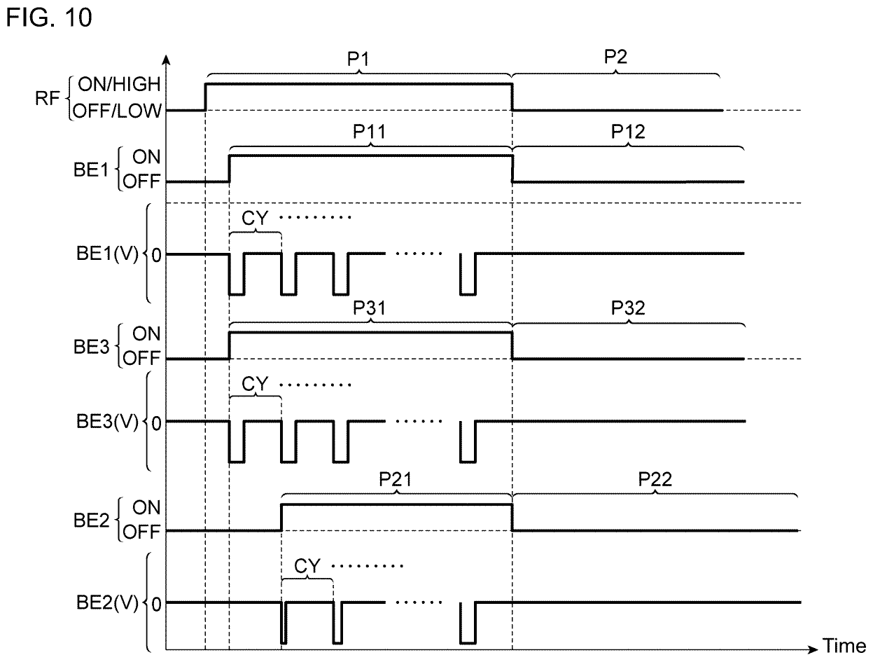

FIGS. 9 and 10 will now be referred to. FIG. 9 is a diagram of a plasma processing apparatus according to still another exemplary embodiment. FIG. 10 is a timing chart for a plasma processing apparatus according to still another exemplary embodiment. A plasma processing apparatus 1D shown in FIG. 9 will now be described focusing on its differences from the plasma processing apparatus 1B.

The plasma processing apparatus 1D further includes an electrode 1111e as a third electrode. The electrode 1111e is located in the ESC 1111 in the annular portion 111b, similarly to the electrode 1111e in the plasma processing apparatus 1.

In the plasma processing apparatus 1D, the bias power supply system 310 further includes an output of third electrical bias energy BE3. Similarly to the first electrical bias energy BE1, the third electrical bias energy BE3 has the waveform cycle CY and is provided to the electrode 1111e cyclically. The third electrical bias energy BE3 may be generated by a third power supply 313.

The third electrical bias energy BE3 may be bias RF power, similarly to the first electrical bias energy BE1. When the third electrical bias energy BE3 is bias RF power, the output of the third electrical bias energy BE3 in the bias power supply system 310 is electrically coupled to the electrode 1111e through a matcher 313m.

Similarly to the first electrical bias energy BE1, the third electrical bias energy BE3 may include a voltage pulse as shown in FIG. 10. The voltage pulse of the third electrical bias energy BE3 is cyclically applied to the electrode 1111e at the time interval equal to the time length of the waveform cycle CY. For the third electrical bias energy BE3 including the voltage pulse, the plasma processing apparatus 1D may not include the matcher 313m.

The third electrical bias energy BE3 is provided to the electrode 1111e cyclically in an on-period P31. The phase of the third electrical bias energy BE3 in the on-period P31 is synchronized with the phase of the first electrical bias energy BE1 in the on-period P11 and the phase of the second electrical bias energy BE2 in the on-period P21. The third electrical bias energy BE3 provided to the electrode 1111e is stopped in an off-period P32. The on-period P31 and the off-period P32 alternate with each other. A cycle including the on-period P31 and the off-period P32 has the same time length as the cycle including the first period P1 and the second period P2. As shown in FIG. 10, the on-period P31 may be synchronized with the on-period P11, and the off-period P32 may be synchronized with the off-period P12.

The bias power supply system 310 identifies the on-period P31 or the off-period P32 based on a pulse control signal provided from the control circuit 320. The control circuit 320 may use a voltage measurement value obtained by a sensor 313s to generate a pulse control signal. The sensor 313s measures the voltage on a feed line for the third electrical bias energy BE3. The feed line couples the matcher 313m and the electrode 1111e.

The level of the third electrical bias energy BE3 (the power level of the bias RF power or the voltage level of the voltage pulse) is set to cause ions to travel in a direction perpendicular to the edge of the substrate W. The third electrical bias energy BE3 is provided to the electrode 1111e to adjust the thickness of a sheath (plasma sheath) above the edge ring 112. This may correct the direction in which the ions travel to be perpendicular to the edge of the substrate W. The other components of the plasma processing apparatus 1D are the same as the corresponding components of the plasma processing apparatus 1B.

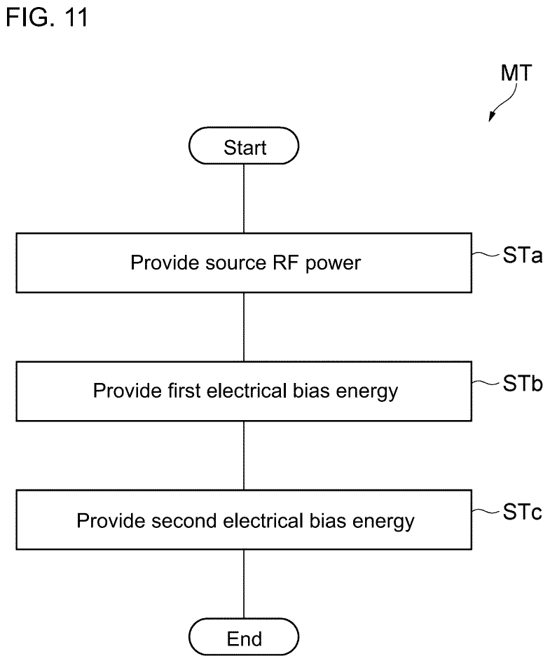

A plasma processing method according to one exemplary embodiment will now be described with reference to FIG. 11. FIG. 11 is a flowchart of a plasma processing method according to one exemplary embodiment. The plasma processing method shown in FIG. 11 (hereafter referred to as a method MT) may be performed using the plasma processing apparatus 1. The method MT includes steps STa, STb, and STc.

In step STa, the source radio-frequency power RF is provided to the RF electrode to generate plasma in the chamber 10. The source radio-frequency power RF is provided in the first period P1 as described above. In the second period P2 that alternates with the first period P1, the source radio-frequency power RF is stopped. In the second period P2, the source radio-frequency power RF having a lower power level than the source radio-frequency power RF in the first period P1 may be provided.

In step STb, the first electrical bias energy BE1 is provided to the first electrode. The first electrode is, for example, the electrode 1111c. The first electrical bias energy BE1 is cyclically provided to the first electrode in the on-period P11 as described above. The first electrical bias energy BE1 is stopped in the off-period P12.

In step STc, the second electrical bias energy BE2 is provided to the second electrode. The second electrode is the electrode 1111e or the electrode 11110. The second electrical bias energy BE2 is cyclically provided to the second electrode in the on-period P21 as described above. The second electrical bias energy BE2 is stopped in the off-period P22.

With the method MT, the first electrical bias energy BE1 and the second electrical bias energy BE2 are adjusted to increase the electric field strength above one of the central portion 111a or the outer portion described above earlier than the electric field strength above the other of the central portion 111a or the outer portion.

In one embodiment, one of the first electrical bias energy BE1 or the second electrical bias energy BE2 may be started to be provided earlier than the other of the first electrical bias energy BE1 or the second electrical bias energy BE2 as described above. This increases the electric field strength above one of the portions to which one of the first electrical bias energy BE1 or the second electrical bias energy BE2 is provided first earlier than the electric field strength above the other portion.

In another embodiment, the voltage level of the voltage pulse of one of the first electrical bias energy BE1 or the second electrical bias energy BE2 may be changed as described above. More specifically, the voltage level of the voltage pulse of the electrical bias energy at the start of bias energy provision may be set to a voltage level different from the voltage level of the voltage pulse of the electrical bias energy after the start of bias energy provision.

In still another embodiment, the power level of one of the first electrical bias energy BE1 or the second electrical bias energy BE2 may be changed as described above. More specifically, the power level of the electrical bias energy at the start of bias energy provision may be set to a level different from the power level of the electrical bias energy after the start of bias energy provision.

In still another embodiment, the duty cycle of one of the first electrical bias energy BE1 or the second electrical bias energy BE2 may be changed as described above. More specifically, the duty cycle at the start of bias energy provision may be set to a value different from the duty cycle of the electrical bias energy after the start of bias energy provision.

Although the exemplary embodiments have been described above, the embodiments are not restrictive, and various additions, omissions, substitutions, and changes may be made. The components in the different embodiments may be combined to form another embodiment.

For example, the first electrode may be an electrode other than the electrode 1111c. For example, the first electrode may be the conductive member in the base 1110.

Various exemplary embodiments E1 to E19 included in the disclosure are described below.

### E1

A plasma processing apparatus, comprising:
a chamber;
a substrate support in the chamber, the substrate support including a central portion on which a substrate is placeable;
a radio-frequency power supply configured to generate source radio-frequency power to generate plasma from a gas in the chamber; and
a bias power supply system configured to provide first electrical bias energy to a first electrode at least in the central portion and second electrical bias energy to a second electrode in an outer portion located outward from the central portion in a radial direction, the radial direction being radial from a center of the central portion,
wherein the bias power supply system adjusts the first electrical bias energy and the second electrical bias energy to increase electric field strength above one of the central portion or the outer portion earlier than electric field strength above the other of the central portion or the outer portion.

The plasma density tends to be higher above the portion above which the electric field strength increases first. In the above embodiment, the electric field strength above one of the central portion or the outer portion increases earlier than the electric field strength above the other of the central portion or the outer portion. The plasma processing apparatus according to the above embodiment can thus adjust the distribution of the plasma density in the radial direction in the chamber.

### E2

The plasma processing apparatus according to E1, wherein
each of the first electrical bias energy and the second electrical bias energy has a waveform cycle, and is bias radio-frequency power or includes a voltage pulse generated cyclically, and
the bias power supply system starts providing one of the first electrical bias energy or the second electrical bias energy earlier than the other of the first electrical bias energy or the second electrical bias energy.

### E3

The plasma processing apparatus according to E1, wherein
each of the first electrical bias energy and the second electrical bias energy is bias radio-frequency power having a waveform cycle, and
the bias power supply system sets a power level of one of the first electrical bias energy or the second electrical bias energy at a start of bias energy provision to a level different from a power level of the one of the first electrical bias energy or the second electrical bias energy after the start of bias energy provision.

### E4

The plasma processing apparatus according to E1, wherein
each of the first electrical bias energy and the second electrical bias energy has a waveform cycle and includes a voltage pulse generated cyclically, and
the bias power supply system sets a voltage level of the voltage pulse of one of the first electrical bias energy or the second electrical bias energy at a start of bias energy provision to a voltage level different from a voltage level of the voltage pulse of the one of the first electrical bias energy or the second electrical bias energy after the start of bias energy provision.

### E5

The plasma processing apparatus according to E1, wherein
each of the first electrical bias energy and the second electrical bias energy has a waveform cycle and includes a voltage pulse generated cyclically, and
the bias power supply system sets a duty cycle of one of the first electrical bias energy or the second electrical bias energy at a start of bias energy provision to a value different from a duty cycle of the one of the first electrical bias energy or the second electrical bias energy after the start of bias energy provision.

### E6

The plasma processing apparatus according to any one of E1 to E5, wherein
the radio-frequency power supply starts providing the source radio-frequency power earlier or later than a time at which at least one of the first electrical bias energy or the second electrical is started to be provided.

### E7

The plasma processing apparatus according to any one of E2 to E5, wherein
the source radio-frequency power is started to be provided earlier or later than at least one of the first electrical bias energy or the second electrical bias energy by a time length corresponding to five or fewer waveform cycles of the first electrical bias energy or the second electrical bias energy.

### E8

The plasma processing apparatus according to any one of E1 to E5, wherein
the radio-frequency power supply starts providing the source radio-frequency power at a same time as at least one of the first electrical bias energy or the second electrical bias energy is started to be provided.

### E9

The plasma processing apparatus according to any one of E2 to E5, wherein
one of the first electrical bias energy or the second electrical bias energy is started to be provided earlier or later than the other of the first electrical bias energy or the second electrical bias energy by a time length corresponding to five or fewer waveform cycles of the first electrical bias energy or the second electrical bias energy.

### E10

The plasma processing apparatus according to any one of E1 to E6, wherein
the bias power supply system matches a phase of the first electrical bias energy and a phase of the second electrical bias energy to each other.

### E11

The plasma processing apparatus according to any one of E1 to E10, wherein
each of the first electrical bias energy, the second electrical bias energy, and the source radio-frequency power is started to be provided at a time determined based on a past process result or light intensity in the chamber or at a time stored in a database.

### E12

The plasma processing apparatus according to any one of E1 to E11, wherein
the outer portion is a portion on which an edge ring is placeable.

### E13

The plasma processing apparatus according to any one of E1 to E11, wherein
the outer portion is located, in the radial direction, outward from an annular portion on which an edge ring is placeable.

### E14

A plasma processing method, comprising:
providing source radio-frequency power to generate plasma in a chamber in a plasma processing apparatus;
providing first electrical bias energy to a first electrode in a substrate support, the substrate support being located in the chamber and including a central portion on which a substrate is placeable, the first electrode being located at least in the central portion; and
providing second electrical bias energy to a second electrode, the second electrode being located in an outer portion located outward from the central portion in a radial direction, the radial direction being radial from a center of the central portion,
wherein the first electrical bias energy and the second electrical bias energy are adjusted to increase electric field strength above one of the central portion or the outer portion earlier than electric field strength above the other of the central portion or the outer portion.

### E15

The plasma processing method according to E14, wherein
each of the first electrical bias energy and the second electrical bias energy has a waveform cycle, and is bias radio-frequency power or includes a voltage pulse generated cyclically, and
one of the first electrical bias energy or the second electrical bias energy is started to be provided earlier than the other of the first electrical bias energy or the second electrical bias energy.

### E16

The plasma processing method according to E14, wherein
each of the first electrical bias energy and the second electrical bias energy is bias radio-frequency power having a waveform cycle, and
a power level of one of the first electrical bias energy or the second electrical bias energy at a start of bias energy provision is set to a level different from a power level of the one of the first electrical bias energy or the second electrical bias energy after the start of bias energy provision.

### E17

The plasma processing method according to E14, wherein
each of the first electrical bias energy and the second electrical bias energy has a waveform cycle and includes a voltage pulse generated cyclically, and
a voltage level of the voltage pulse of one of the first electrical bias energy or the second electrical bias energy at a start of bias energy provision is set to a voltage level different from a voltage level of the voltage pulse of the one of the first electrical bias energy or the second electrical bias energy after the start of bias energy provision.

### E18

The plasma processing method according to E14, wherein
each of the first electrical bias energy and the second electrical bias energy has a waveform cycle and includes a voltage pulse generated cyclically, and
a duty cycle of one of the first electrical bias energy or the second electrical bias energy at a start of bias energy provision is set to a value different from a duty cycle of the one of the first electrical bias energy or the second electrical bias energy after the start of bias energy provision.

### E19

A plasma processing apparatus, comprising:
a chamber;
a substrate support in the chamber, the substrate support including a central portion on which a substrate is placeable;
a radio-frequency power supply configured to generate source radio-frequency power to generate plasma from a gas in the chamber;
a first electrode in the central portion;
a second electrode in an outer portion located outward from the central portion in a radial direction, the radial direction being radial from a center of the central portion; and
a bias power supply system configured to provide first electrical bias energy to the first electrode and second electrical bias energy to the second electrode,
wherein the bias power supply system starts providing one of the first electrical bias energy or the second electrical bias energy earlier than the other of the first electrical bias energy or the second electrical bias energy, and
the radio-frequency power supply starts providing the source radio-frequency power earlier than a time at which the first electrical bias energy is started to be provided and a time at which the second electrical bias energy is started to be provided.

The exemplary embodiments according to the disclosure have been described by way of example, and various changes may be made without departing from the scope and spirit of the disclosure. The exemplary embodiments described above are thus not restrictive, and the true scope and spirit of the disclosure are defined by the appended claims.

### REFERENCE SIGNS LIST

1 Plasma processing apparatus
10 Chamber
11 Substrate support
300 RF power supply
310 Bias power supply system
RF Source radio-frequency power
BE1 First electrical bias energy
BE2 Second electrical bias energy

1. A plasma processing apparatus, comprising:
a chamber;
a substrate support in the chamber, the substrate support including a central portion on which a substrate is placeable;
a radio-frequency power supply configured to generate source radio-frequency power to generate plasma from a gas in the chamber; and
a bias power supply system configured to:
provide first electrical bias energy to a first electrode at least in the central portion, and
provide second electrical bias energy to a second electrode in an outer portion located outward from the central portion in a radial direction, the radial direction being radial from a center of the central portion,
wherein the bias power supply system is configured to adjust the first electrical bias energy and the second electrical bias energy to increase electric field strength above one of the central portion or the outer portion earlier than electric field strength above the other of the central portion or the outer portion.

2. The plasma processing apparatus according to claim 1, wherein
each of the first electrical bias energy and the second electrical bias energy has a waveform cycle, and is bias radio-frequency power or includes a voltage pulse generated cyclically, and
the bias power supply system is configured to start providing one of the first electrical bias energy or the second electrical bias energy earlier than the other of the first electrical bias energy or the second electrical bias energy.

3. The plasma processing apparatus according to claim 1, wherein
each of the first electrical bias energy and the second electrical bias energy is bias radio-frequency power having a waveform cycle, and
the bias power supply system is configured to set a power level of one of the first electrical bias energy or the second electrical bias energy at a start of bias energy provision to a level different from a power level of the one of the first electrical bias energy or the second electrical bias energy after the start of bias energy provision.

4. The plasma processing apparatus according to claim 1, wherein
each of the first electrical bias energy and the second electrical bias energy has a waveform cycle and includes a voltage pulse generated cyclically, and
the bias power supply system is configured to set a voltage level of the voltage pulse of one of the first electrical bias energy or the second electrical bias energy at a start of bias energy provision to a voltage level different from a voltage level of the voltage pulse of the one of the first electrical bias energy or the second electrical bias energy after the start of bias energy provision.

5. The plasma processing apparatus according to claim 1, wherein
each of the first electrical bias energy and the second electrical bias energy has a waveform cycle and includes a voltage pulse generated cyclically, and
the bias power supply system is configured to set a duty cycle of one of the first electrical bias energy or the second electrical bias energy at a start of bias energy provision to a value different from a duty cycle of the one of the first electrical bias energy or the second electrical bias energy after the start of bias energy provision.

6. The plasma processing apparatus according to claim 1, wherein
the radio-frequency power supply is configured to start providing the source radio-frequency power earlier or later than a time at which at least one of the first electrical bias energy or the second electrical is started to be provided.

7. The plasma processing apparatus according to claim 2, wherein
the radio-frequency power supply is configured to start the source radio-frequency power earlier or later than at least one of the first electrical bias energy or the second electrical bias energy by a time length corresponding to five or fewer waveform cycles of the one of first electrical bias energy or the second electrical bias energy.

8. The plasma processing apparatus according to claim 2, wherein
the radio-frequency power supply is configured to start providing the source radio-frequency power at a same time as at least one of the first electrical bias energy or the second electrical bias energy is started to be provided.

9. The plasma processing apparatus according to claim 2, wherein
the bias power supply system is configured to start one of the first electrical bias energy or the second electrical bias energy earlier or later than the other of the first electrical bias energy or the second electrical bias energy by a time length corresponding to five or fewer waveform cycles of the first electrical bias energy or the second electrical bias energy.

10. The plasma processing apparatus according to claim 1, wherein
the bias power supply system matches a phase of the first electrical bias energy and a phase of the second electrical bias energy to each other.

11. The plasma processing apparatus according to claim 1, wherein
each of the first electrical bias energy, the second electrical bias energy, and the source radio-frequency power is started at a time determined based on a past process result or based on light intensity in the chamber or at a time stored in a database.

12. The plasma processing apparatus according to claim 1, wherein
an edge ring is placeable on the outer portion.

13. The plasma processing apparatus according to claim 1, wherein
the substrate support includes the central portion and an electrostatic member inside the central portion, and
the central portion is a ceramic member.

14. A plasma processing method, comprising:
providing source radio-frequency power to generate plasma in a chamber in a plasma processing apparatus;
providing first electrical bias energy to a first electrode in a substrate support, the substrate support being located in the chamber and including a central portion on which a substrate is placeable, the first electrode being located at least in the central portion; and
providing second electrical bias energy to a second electrode, the second electrode being located in an outer portion located outward from the central portion in a radial direction, the radial direction being radial from a center of the central portion,
wherein the first electrical bias energy and the second electrical bias energy are adjusted to increase electric field strength above one of the central portion or the outer portion earlier than electric field strength above the other of the central portion or the outer portion.

15. The plasma processing method according to claim 14, wherein
each of the first electrical bias energy and the second electrical bias energy has a waveform cycle, and is bias radio-frequency power or includes a voltage pulse generated cyclically, and
one of the first electrical bias energy or the second electrical bias energy is started to be provided earlier than the other of the first electrical bias energy or the second electrical bias energy.

16. The plasma processing method according to claim 14, wherein
each of the first electrical bias energy and the second electrical bias energy is bias radio-frequency power having a waveform cycle, and
a power level of one of the first electrical bias energy or the second electrical bias energy at a start of bias energy provision is set to a level different from a power level of the one of the first electrical bias energy or the second electrical bias energy after the start of bias energy provision.

17. The plasma processing method according to claim 14, wherein
each of the first electrical bias energy and the second electrical bias energy has a waveform cycle and includes a voltage pulse generated cyclically, and
a voltage level of the voltage pulse of one of the first electrical bias energy or the second electrical bias energy at a start of bias energy provision is set to a voltage level different from a voltage level of the voltage pulse of the one of the first electrical bias energy or the second electrical bias energy after the start of bias energy provision.

18. The plasma processing method according to claim 14, wherein
each of the first electrical bias energy and the second electrical bias energy has a waveform cycle and includes a voltage pulse generated cyclically, and
a duty cycle of one of the first electrical bias energy or the second electrical bias energy at a start of bias energy provision is set to a value different from a duty cycle of the one of the first electrical bias energy or the second electrical bias energy after the start of bias energy provision.

19. A plasma processing apparatus, comprising:
a chamber;
a substrate support in the chamber, the substrate support including a central portion on which a substrate is placeable;
a radio-frequency power supply configured to generate source radio-frequency power to generate plasma from a gas in the chamber;
a first electrode in the central portion;
a second electrode in an outer portion located outward from the central portion in a radial direction, the radial direction being radial from a center of the central portion; and
a bias power supply system configured to provide first electrical bias energy to the first electrode and second electrical bias energy to the second electrode,
wherein the bias power supply system starts providing one of the first electrical bias energy or the second electrical bias energy earlier than the other of the first electrical bias energy or the second electrical bias energy, and
the radio-frequency power supply is configured to start providing the source radio-frequency power earlier than a time at which the first electrical bias energy is started and a time at which the second electrical bias energy is started.

20. The plasma processing apparatus according to claim 19, wherein
each of the first electrical bias energy and the second electrical bias energy has a waveform cycle, and is bias radio-frequency power or includes a voltage pulse generated cyclically, and
the bias power supply system is configured to start providing one of the first electrical bias energy or the second electrical bias energy earlier than the other of the first electrical bias energy or the second electrical bias energy.
